(19) United States
(12) Patent Application Publication
(10) Pub. No.: US 2021/0050720 A1
(43) Pub. Date: Feb. 18, 2021

(54) OPERATION DEVICE AND OPERATION SYSTEM

(71) Applicant: NEC Platforms, Ltd., Kawasaki-shi, Kanagawa (JP)

(72) Inventor: Yoshihiro OHSHITA, Kanagawa (JP)

(73) Assignee: NEC Platforms, Ltd., Kawasaki-shi, Kanagawa (JP)

(21) Appl. No.: 16/966,229

(22) PCT Filed: Mar. 5, 2019
(86) PCT No.: PCT/JP2019/008597

§ 371 Date: Jul. 30, 2020

(30) Foreign Application Priority Data
Mar. 8, 2018 (JP) 2018-041921

(51) Int. Cl. H02H 9/02

(52) U.S. Cl. CPC H02H 9/025

(57) ABSTRACT

In order to widen the options of power supply devise to be applied, this operation device is provided with: an operation unit that operates by the current supplied from a power supply; and an adjustment unit that lowers the value of the supplied current when the value of the supplied current exceeds a threshold value.

### TECHNICAL FIELD

The present invention relates to a device that alleviates an overcurrent.

### BACKGROUND ART

A system that detects an overcurrent supplied from a power supply to a device and adjusts a current value is generally utilized (refer to PTLs 1 and 2).

FIG. 1 is a conceptual diagram illustrating a configuration of a fan system 301 that is an example of a general fan system that adjusts an overcurrent supplied from a power supply to a fan.

The fan system 301 includes a power supply device 201 and a fan device 101.

The power supply device 201 includes a current supply unit 206, an adjustment unit 211, a communication unit 221, and a recording unit 226.

The fan device 101 includes a fan 106, a detection unit 111, a capacitor 121, and a communication unit 141.

The fan 106 of the fan device 101 operates by a current supplied from the power supply device 201. The fan 106 is for cooling a heat generation device, for example.

The detection unit 111 detects a supply current supplied from the power supply device 201 to the fan 106. Then, the detection unit 111 sends current information representing the detected current, to the communication unit 141.

The communication unit 141 sequentially sends the current information to the communication unit 221 of the power supply device 201.

The communication unit 221 sends the current information received from the fan device 101 to a processing unit 216.

The processing unit 216 sequentially determines whether a current value represented by the current information sent from the communication unit 221 exceeds a threshold value that the recording unit 226 holds. Then, the processing unit 216 outputs, to the adjustment unit 211, when determining that the current value exceeds the threshold value, adjustment information being information for causing performing adjustment.

The adjustment unit 211 reduces, when the adjustment information is input from the processing unit 216, the supply current supplied from the current supply unit 206 to the fan device.

The capacitor 121 is inserted for the purpose of stabilizing a supply voltage to the fan 106.

Herein, PTL 1 discloses an overcurrent protection circuit that detects a current supplied from a current supply unit to a load by a current detection unit, and limits, when a detected current of the current detection unit exceeds a set value, the current supplied from the current supply unit to the load.

PTL 2 discloses a semiconductor device that outputs, based on a first detection signal, when a drain-source voltage is smaller than a first reference value, a second detection signal as it is without latching, and controls an output transistor to OFF or ON.

In addition, PTL 3 discloses a switching regulator circuit for pulse width modulation (PWM) control in connection with the present invention.

### CITATION LIST

### Patent Literature

[PTL 1] Japanese Unexamined Patent Application Publication No. H06-276734

[PTL 2] Japanese Unexamined Patent Application Publication No. 2013-255117

[PTL 3] Japanese Unexamined Patent Application Publication No. 2000-139072

### SUMMARY OF INVENTION

### Technical Problem

Some commercially available power supply devices fail to include a mechanism that adjusts a current value according to received information. As the power supply device 201 of the fan system 301 illustrated in FIG. 1, one including a mechanism that adjusts a current value needs to be used. Thus, there is a problem that a range of options for power supply devices at a time when the fan system 301 is manufactured narrows.

An object of the present invention is to provide an operation device and the like that are able to expand options for power supply devices to be applied.

### Solution to Problem

An operation device according to the present invention includes: an operation unit that operates by a supply current from a power supply; and an adjustment unit that decreases a value of the supply current when a current value of the supply current exceeds a threshold value.

### Advantageous Effects of Invention

The operation device and the like according to the present invention are able to expand options for power supply devices to be applied.

### BRIEF DESCRIPTION OF DRAWINGS

FIG. 1 is a conceptual diagram illustrating a configuration example of a general fan system that adjusts an overcurrent supplied from a power supply to a fan.

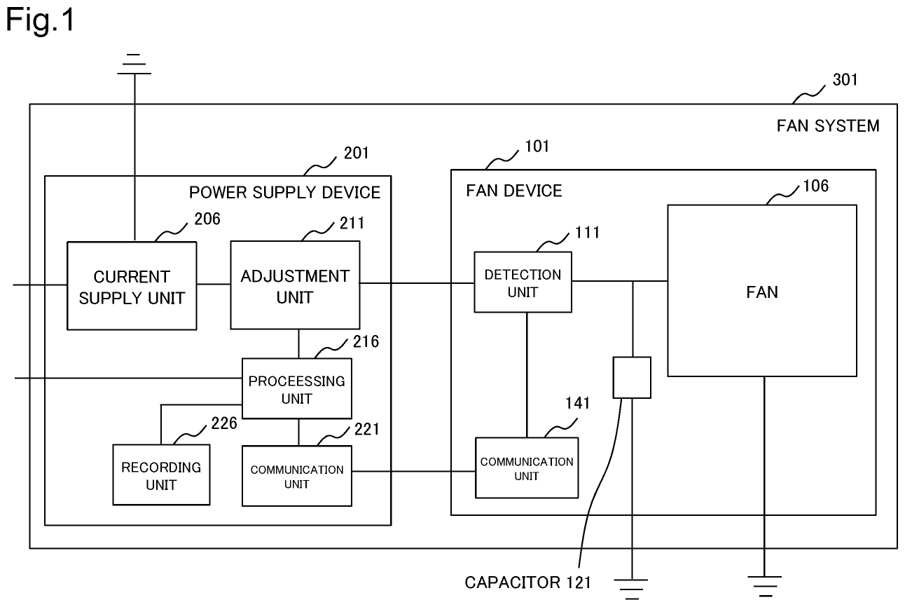

FIG. 2 is a conceptual diagram illustrating a configuration example of the fan system according to a first example embodiment.

FIG. 3 is an imaginary diagram illustrating a state in which an overcurrent is suppressed in the fan system according to the first example embodiment.

FIG. 4 is a conceptual diagram illustrating a configuration example of a fan system according to a second example embodiment.

FIG. 5 is an imaginary diagram illustrating a state in which an overcurrent is suppressed in the fan system according to the second example embodiment.

FIG. 6 is a conceptual diagram illustrating a first configuration example of a fan system according to a third example embodiment.

FIG. 7 is a conceptual diagram illustrating a second configuration example of the fan system according to the third example embodiment.

FIG. 8 is a block diagram illustrating a minimum configuration of the operation device according to the example embodiments.

### EXAMPLE EMBODIMENT

### First Example Embodiment

A first example embodiment is an example embodiment relating to a fan device including a mechanism that suppresses an overcurrent.

### [Configuration and Operation]

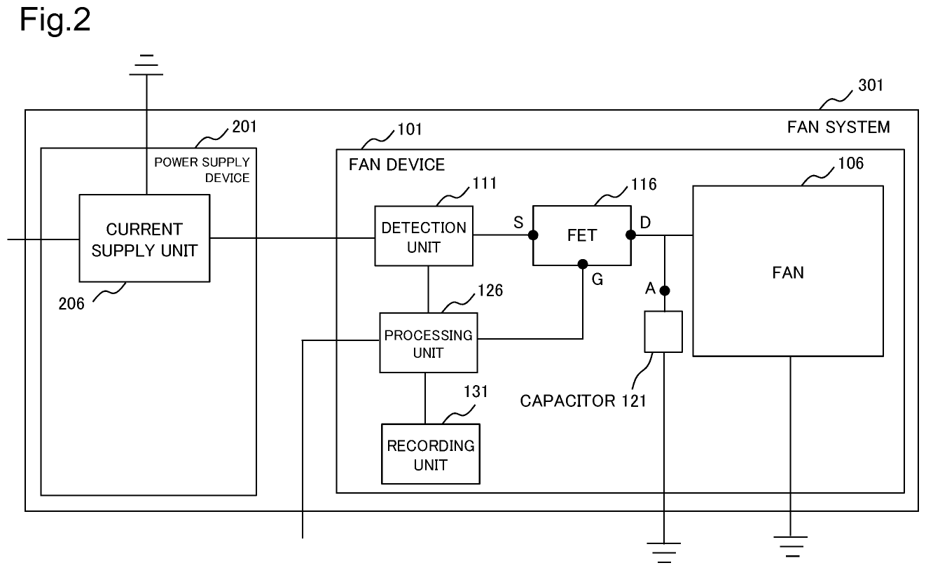

FIG. 2 is a conceptual diagram illustrating a configuration of a fan system 301 that is an example of the fan system according to the first example embodiment.

The fan system 301 includes a power supply device 201 and a fan device 101.

The power supply device 201 includes a current supply unit 206.

The fan device 101 includes a fan 106, a detection unit 111, an FET 116, a capacitor 121, a processing unit 126, and a recording unit 131. Here, FET is an acronym for a field effect transistor.

The fan 106 operates by a supply current supplied from the power supply device 201. The fan 106 is for cooling a target object, for example.

The capacitor 121 is for stabilizing the supply current.

The detection unit 111 sequentially detects a current value of the supply current. Then, the detection unit 111 sequentially inputs current information representing the current value to the processing unit 126.

The processing unit 126 sequentially determines whether the current value exceeds a threshold value that the recording unit 131 holds. Then, the processing unit 126 switches, when determining that the current value exceeds the threshold value, a voltage level of a gate (G) terminal of the FET from “0” to “1”. The processing unit 126 thereafter switches, when determining that the current value falls below the threshold value, the voltage level of the gate (G) terminal of the FET from “1” to “0”.

The FET 116 operates, when the voltage level of the G terminal is switched from “0” to “1”, in a direction of insulating between a source (S) and a drain (D). By this operation, the current value decreases.

On the other hand, the FET 116 operates, when the voltage level of the G terminal is switched from “1” to “0”, in a direction of electrically conducting between an S terminal and a D terminal.

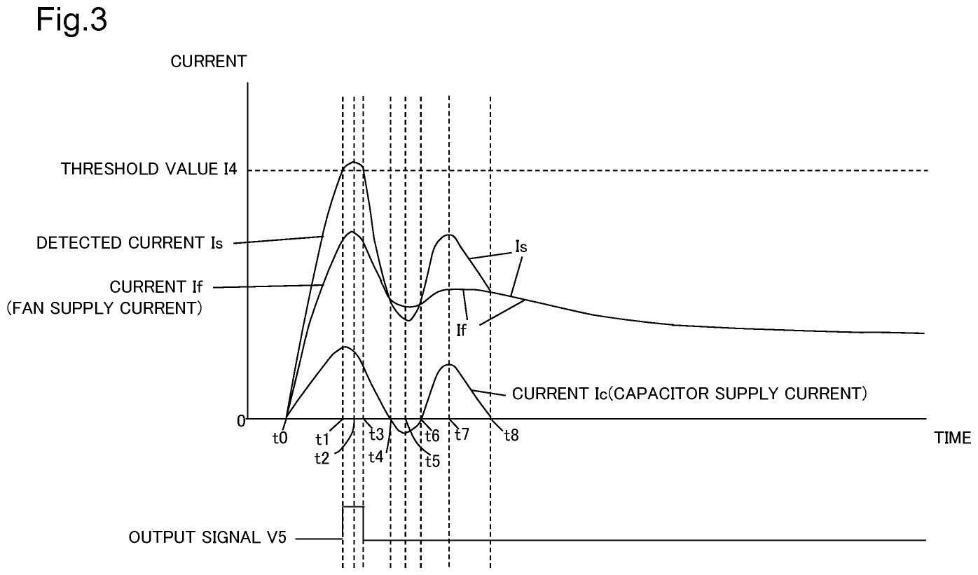

FIG. 3 is an imaginary diagram illustrating a state in which the overcurrent is suppressed in the fan system 301 illustrated in FIG. 2.

In FIG. 3, it is assumed that supply of the supply current from the power supply device 201 to the fan device 101 is started at a time to.

A detected current Is illustrated in FIG. 3 is the current value of the supply current detected by the detection unit 111. The detected current Is is a sum of currents supplied from the power supply device 201 to the fan 106 and the capacitor 121.

The detected current Is increases with the elapse of time at the time t0 or later A reason why a time is required for a rise of the detected current Is is due to the influence of a capacitance or conductance existing or being parasitic in a path through which the supply current represented by the detected current Is passes.

Then, the detected current Is exceeds a threshold value 14 at a time t1. The threshold value 14 is the previously mentioned threshold value that the recording unit 131 illustrated in FIG. 2 holds.

Then, the processing unit 126 determines that the supply current exceeds the threshold value. Then, the processing unit 126 switches a voltage of the G terminal of the FET 116 from “0” to “1”. By this switching, the FET 116 operates in a direction of isolating between the S terminal and the D terminal. By the operation, the detected current Is lowers after a peak up to a time t2 is taken.

Herein, a reason why a time is required without the lowering being performed momentarily assumes a processing delay in the processing unit 126 and the influence of an operating time related to the operation in the FET 116.

The detected current Is falls below the threshold value 14 at a time t3. The processing unit 126 thereby determines that the supply current falls below the threshold value. Then, the processing unit 126 switches the voltage of the G terminal of the FET 116 from “1” to “0”.

Afterwards, the FET 116 performs an operation of electrically conducting between the S terminal and the D terminal. By this operation, the detected current Is turns over from lowering to rising. Herein, a reason why a time is required without turnover of the detected current from lowering to rising being performed momentarily assumes processing delays in the detection unit 111 and the processing unit 126 and the influence of the operating time related to the operation in the FET 116. In FIG. 3, the rising appears at a time t5 or later.

Between a time t4 and a time t6, a current If that is a current flowing in the fan 106 illustrated in FIG. 2 exceeds the detected current Is and a current Ic that is a current supplied to the capacitor 121 becomes negative. This presupposes that, between the times t4 and t6, an electric potential of a terminal A imparted by the capacitor 121 exceeds an electric potential of a terminal D of the FET 116, and a current is thereby supplied from the capacitor 121 to the fan 106.

At the time t6 or later, a current is supplied from the power supply device 201 to the capacitor 121 and the fan 106 illustrated in FIG. 2.

The current Ic becomes 0 at a time t8. This is because charging from the current supply unit 206 to the capacitor 121 is completed.

At the time t8 or later, the detected current Is and the current If are substantially equal to each other. A reason why the detected current Is and the current If gradually decrease at the time t8 or later assumes that such a gradual decrease is due to a rise of the number of rotations of a motor, although not illustrated, included in the fan 106. The detected current Is and the current If become substantially constant later when the number of rotations of the motor becomes constant.

### Advantageous Effects

The fan system according to the first example embodiment causes, when a supply current supplied from a power supply device to a fan exceeds a threshold value, the FET to perform an operation in a direction of cutting off the supply current to the fan. Thus, the fan system makes it possible to suppress the overcurrent.

The fan system performs the operation by switching a gate voltage supplied from a processing unit to an FET without communication involving transmission and reception. Since there is no transmission and reception processing for performing the operation, the fan system can also suppress such a short-time overcurrent that may occur when power is supplied.

Further, in the fan system, a fan device includes a configuration that performs the operation. Thus, the power supply device 201 may include a current supply unit. Therefore, the fan system makes it possible to increase a range of options for power supply devices at the time of actual manufacturing.

### Second Example Embodiment

A second example embodiment is an example embodiment relating to a fan system that suppresses an overcurrent flowing in a fan when a supply current is adjusted by PWM control. Here, PWM is an acronym for pulse width modulation. Such PWM control is well-known art, and is disclosed in PTL 3, for example.

### [Configuration and Operation]

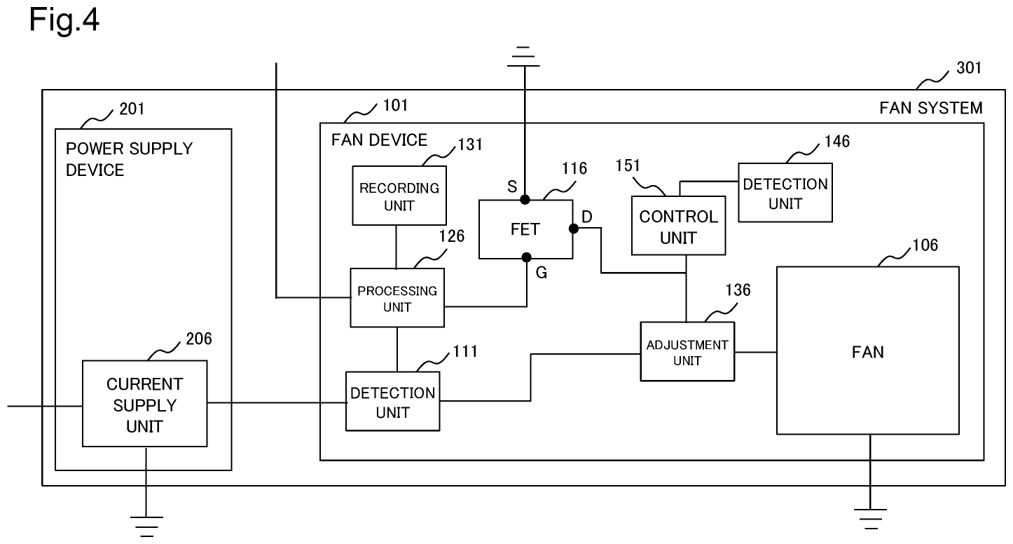

FIG. 4 is a conceptual diagram illustrating a configuration of a fan system 301 that is an example of a fan system according to a second example embodiment.

The fan system 301 includes a power supply device 201 and a fan device 101.

A description of the power supply device 201 illustrated in FIG. 4 is the same as a description of the power supply device 201 illustrated in FIG. 2.

The fan device 101 includes a fan 106, a detection unit 111, an FET 116, a processing unit 126, a recording unit 131, an adjustment unit 136, a control unit 151, and a detection unit 146.

The detection unit 111 sequentially detects an average value of a predetermined period of time of a current supplied from the power supply device 201 to the fan 106. Herein, a reason why a target to be detected by the detection unit 111 is the average value is that, as described later, the adjustment unit 136 makes an input of a supply current to the adjustment unit 136 intermittent by a PWM signal input from the control unit 151. The detection unit 111 sequentially inputs current information representing the detected average value to the processing unit 126.

The processing unit 126 sequentially determines whether a current value represented by the current information sent from the detection unit 111 exceeds a threshold value that the recording unit 131 holds. Then, the processing unit 126 switches, when determining that the current value exceeds the threshold value, a voltage level of a G terminal from “1” to “0”. Afterwards, the processing unit 126 switches, when determining that the current value falls below the threshold value, the voltage level of the G terminal from “0” to “1”.

The detection unit 146 measures a temperature of an object to be cooled by the fan 106. Then, the detection unit 146 sends temperature information representing the temperature to the control unit 151.

The control unit 151 performs PWM control for the adjustment unit 136 according to the temperature information.

The adjustment unit 136 generates an intermediate current by superimposing a direct current bias current on a current acquired by synchronizing a supply current input from the power supply device 201 with a change timing of a PWM signal input from the control unit 151 and repeating ON and OFF. The PWM signal is a signal repeating levels of 1 and 0 at a predetermined cycle. The adjustment unit 136 generates the intermediate current by a DC-AC converter, for example. Herein, DC is an acronym for direct current. Also, AC is an acronym for alternating current.

The adjustment unit 136 performs smoothing processing for the intermediate current, and converts the smoothened current to a direct current. A DC current value of the direct current depends on a duty ratio of the PWM signal. Thus, the DC current value is adjusted by a duty ratio of the PWM signal. The DC current value is substantially equal to the average value detected by the detection unit 111, at a level at which a conversion loss in the adjustment unit can be ignored.

When a period of time during which a signal level of the PWM signal is “0” continues for a certain period of time or more, the DC current value approaches a DC current value of the bias current. Note that the bias current may be 0.

The FET 116 makes electrically conductive between an S terminal and a D terminal when the processing unit 126 switches a voltage level of a G terminal from “1” to “0”. By the electrical conduction, the D terminal is connected to a ground. By this connection, the signal level of the PWM control signal sent from the control unit 151 to the adjustment unit 136 always becomes “0”. In other words, by the electrical conduction, the PWM signal input to the adjustment unit 136 is disabled.

The FET 116 insulates between the S terminal and the D terminal when the processing unit 126 thereafter switches the voltage level of the G terminal from “0” to “1”. By the insulation, the D terminal is insulated from a ground. By this insulation, the PWM control signal sent from the control unit 151 to the adjustment unit 136 is enabled.

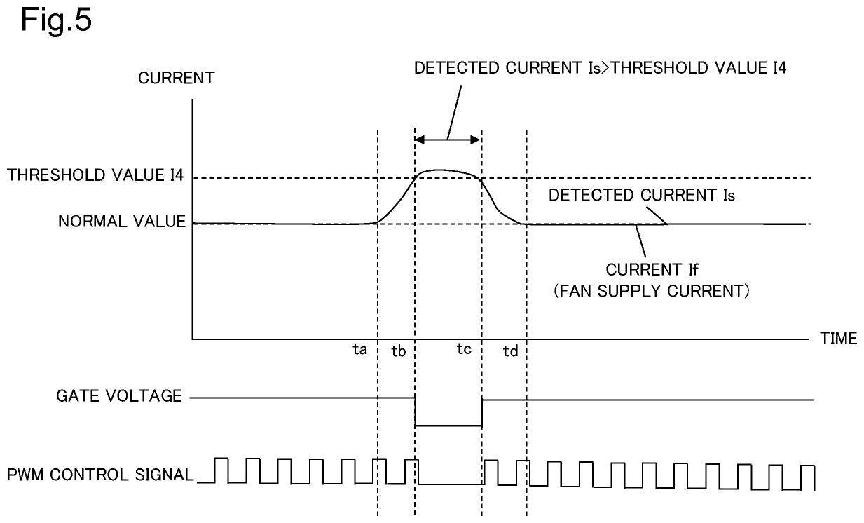

FIG. 5 is an imaginary diagram illustrating a state in which an overcurrent is suppressed in the fan system 301 illustrated in FIG. 4.

In the fan system 301 illustrated in FIG. 4, a detected current Is that is the average value supplied from the power supply device 201 to the fan device 101 is equal to a current If supplied to the fan 106.

It is assumed that, as illustrated in FIG. 5, the detected current Is starts to rise due to a fluctuation at a time ta, and exceeds a threshold value 14 at a time tb.

In that case, the processing unit 126 illustrated in FIG. 4 determines that the detected current Is exceeds the threshold value 14 at the time tb. Then, the processing unit 126 switches a gate voltage of the FET 116 to a voltage level “0”.

The FET 116 performs an operation in a direction of short-circuiting between the S terminal and the D terminal by switching a gate signal to the voltage level “0”.

Thus, a further rise of the detected current Is can be suppressed when the current Is exceeds the threshold value 14 only slightly as illustrated in FIG. 5.

It is assumed that the processing unit 126 thereafter determines that the detected current Is falls below the threshold value 14 at a point of time when having passed a time tc.

Then, the processing unit 126 switches the gate voltage of the FET 116 to a voltage level of “1”.

The FET 116 performs an operation in a direction of insulating between the S terminal and the D terminal by switching the gate signal to the voltage level of “1”.

It is assumed that the detected current Is thereafter lowers and returns to a normal value at a time td or later. This presupposes that, at the time td or later, abnormality of a supply current supplied by the power supply device 201 is eliminated.

### Advantageous Effects

In the fan system according to the second example embodiment, a fan device disables, when a detected current exceeds a threshold value, such an excess by connecting a PWM control signal input terminal of an adjustment unit to a ground, due to a short-circuit between a source and a drain of an FET. The fan system makes it possible to prevent, by the connection, a supply current to a fan from becoming an overcurrent.

In the fan system, a fan device includes a configuration that performs the operation. Thus, the power supply device 201 may include a current supply unit. Therefore, the fan system makes it possible to increase a range of options for power supply devices at the time of actual manufacturing.

### Third Example Embodiment

A third example embodiment is an example embodiment relating to a fan system in which a power supply device supplies a I/O signal that drives an FET to a fan device.

### [Configuration and Operation]

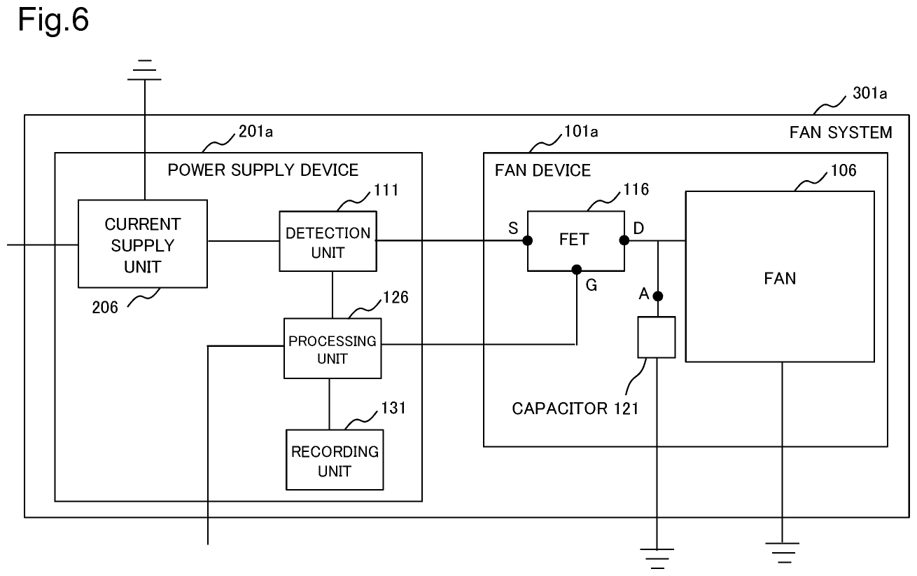

FIG. 6 is a conceptual diagram illustrating a configuration of a fan system 301a that is a first example of the fan system according to the third example embodiment.

The fan system 301a is different from the fan system 301 illustrated in FIG. 2 in that, instead of a fan device 101a, a power supply device 201a includes a detection unit 111, a processing unit 126, and a recording unit 131.

Then, the detection unit 111, the processing unit 126, and the recording unit 131 perform the operation set forth in the description of FIG. 2 inside the power supply device 201a.

Except the above, a description of the fan system 301a is the same as the description of the fan system 301 illustrated in FIG. 2. However, the fan system 301, the power supply device 201, and the fan device 101 in the description of the fan system 301 illustrated in FIG. 2 is reread as the fan system 301a, the power supply device 201a, and the fan device 101a in this sequential order. Also, when the above description and the description of FIG. 2 are contradictory, the above description is prioritized.

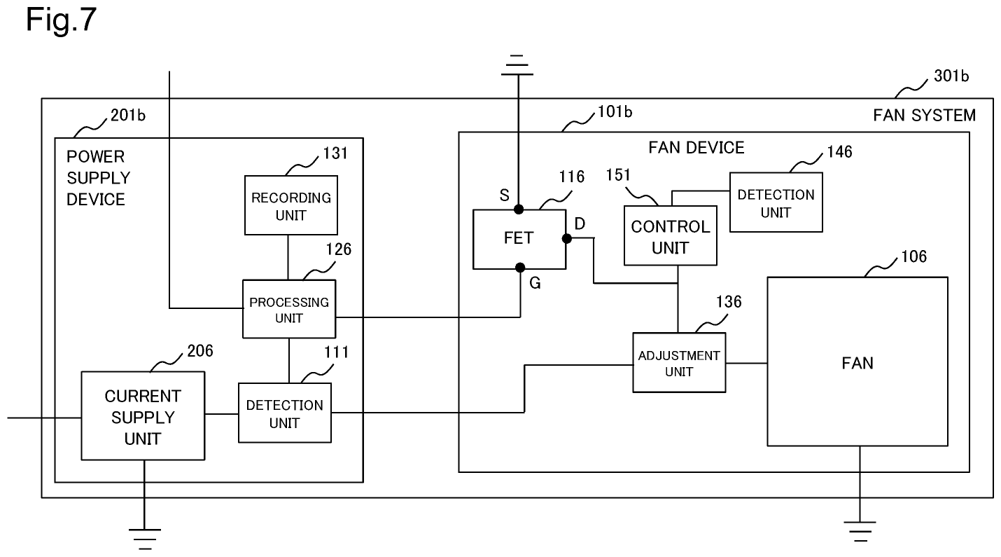

FIG. 7 is a conceptual diagram illustrating a configuration of a fan system 301b that is a second example of the fan system according to the third example embodiment.

The fan system 301b is different from the fan system 301 illustrated in FIG. 4 in that, instead of a fan device 101b, a power supply device 201b includes a detection unit 111, a processing unit 126, and a recording unit 131.

Then, the detection unit 111, the processing unit 126, and the recording unit 131 perform the operation set forth in the description of FIG. 4 inside the power supply device 201b.

Except the above, a description of the fan system 301b is the same as the description of the fan system 301 illustrated in FIG. 4. However, the fan system 301, the power supply device 201, and the fan device 101 in the description of the fan system 301 illustrated in FIG. 4 is reread as the fan system 301b, the power supply device 201b, and the fan device 101b in this sequential order. Also, when the above description and the description of FIG. 4 are contradictory, the above description is prioritized.

### Advantageous Effects

When the power supply device includes a detection unit, a processing unit, and a recording unit, the fan system according to the third example embodiment can attain the same advantageous effects as the fan systems according to the first and second example embodiments by utilizing a power supply device as it is or merely making a slight change in outputting the I/O signal.

The above description of the example embodiments has set forth an example in a case where a target device being a device to which a power supply device supplies a current is a fan. However, the target device may be another one, as long as the device operates by supply of a current.

When the target device is an intelligent device such as a central processing unit, the target device can suppress its own current consumption by the I/O signal. Thus, the target device communicates with a power supply device, and processing of monitoring a supply state becomes unnecessary.

In addition, when the target device is a non-intelligent device such as a fan device, the target device cannot suppress current consumption by itself and thus a circuit such as an FET is required. In that case also, the target device can suppress a current by operating the circuit by the I/O signal irrespective of the contents of circuits that perform supply power control using an FET, PWM signal control, or the like.

Further, when a supply current is suppressed by a power supply device, a supply current to all loads to which a current is supplied from the power supply device is suppressed. Thus, a supply current to a device, that is not desired to be suppressed or that must not to be suppressed, is suppressed as well. In contrast to this, the system according to the example embodiment is capable of selecting a target device to which a supply current needs to be suppressed (a fan device in the previously mentioned example) and suppressing only a supply current to the target device.

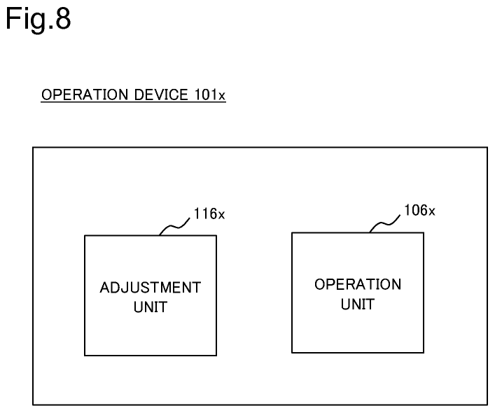

FIG. 8 is a block diagram illustrating a configuration of an operation device 101x that is a minimum configuration of the operation device according to the example embodiments.

The operation device 101x includes an operation unit 106x and an adjustment unit 116x.

The operation unit 106x operates by a supply current from a power supply not illustrated.

The adjustment unit 116x reduces a value of the supply current when a current value of the supply current exceeds a threshold value.

The operation device 101x suppresses an overcurrent of the supply current and thus the power supply does not need to include a mechanism for suppressing an overcurrent of the supply current. Therefore, the operation device 101x makes it possible to increase a range of options for power supply devices at the time of actual manufacturing.

Thus, the operation device 101x attains, by the configuration, advantageous effects set forth in the section entitled [Advantageous Effects of the Invention].

The operation device 101x is the fan device 101 illustrated in FIG. 2 or FIG. 4, for example. Also, the operation unit 106x is the fan 106 illustrated in FIG. 2 or FIG. 4, for example. In addition, the adjustment unit 116x is a configuration made by combining the processing unit 126 and the FET 116 illustrated in FIG. 2 or a configuration made by combining the processing unit 126 and the FET 116 illustrated in FIG. 4, for example. Further, the power supply is the power supply device 201 illustrated in FIG. 2 or FIG. 4, for example.

While the example embodiments of the present invention have been described hereinabove, the present invention is not limited to the example embodiments, and further alteration(s), replacement(s), or adjustment(s) may be made therein without departing from the basic technical idea of the present invention. For example, configurations of the elements illustrated in the drawings are each merely provided as one example for helping understanding of the present invention, and the present invention is not limited to the configurations illustrated in these drawings.

The whole or part of the example embodiments disclosed above can be described as, but not limited to, the following supplementary notes.

(Supplementary Note 1)

An operation device including:

an operation unit that operates by a supply current from a power supply; and

an adjustment unit that decreases, in a case where a current value of the supply current exceeds a threshold value, the value of the supply current.

(Supplementary Note 2)

The operation device according to supplementary note 1, wherein the adjustment unit performs the decrease by actuating a switch.

(Supplementary Note 3)

The operation device according to supplementary note 2, further including

a processing unit that switches a voltage level in the case, wherein

the switch performs the actuation by the switching.

(Supplementary Note 4)

The operation device according to supplementary note 3, wherein

the switch includes a semiconductor switch.

(Supplementary Note 5)

The operation device according to supplementary note 4, wherein

the semiconductor switch is a field effect transistor, and

the voltage level is input to a gate of the field effect transistor.

(Supplementary Note 6)

The operation device according to supplementary note 5, wherein,

when the current value falls below a threshold value after the case, the voltage level is returned to a level before the switching.

(Supplementary Note 7)

The operation device according to any one of supplementary notes 2 to 6, wherein

the actuation is a change of a control signal that adjusts the supply current.

(Supplementary Note 8)

The operation device according to supplementary notes 7, wherein

the change is enabling and disabling.

(Supplementary Note 9)

The operation device according to supplementary note 7 or 8, wherein

the control signal is a pulse width modulation control signal.

(Supplementary Note 10)

The operation device according to any one of supplementary notes 7 to 9, wherein

the control signal performs the adjustment depending on an operation state of the operation unit.

(Supplementary Note 11)

The operation device according to any one of supplementary notes 2 to 10, wherein

the actuation is supply and supply stop of the supply current being input to the operation unit.

(Supplementary Note 12)

The operation device according to any one of supplementary notes 1 to 11, wherein

an input unit of the supply current in the operation unit is grounded via a capacitor.

(Supplementary Note 13)

The operation device according to any one of supplementary notes 1 to 12, wherein

the operation unit is a fan.

(Supplementary Note 14)

The operation device according to any one of supplementary notes 1 to 13, further including

a detection unit that detects the current value.

(Supplementary Note 15)

The operation device according to any one of supplementary notes 1 to 14, further including

a recording unit that holds the threshold value.

(Supplementary Note 16)

An operation system including:

the operation device according to any one of supplementary notes 1 to 15; and

the power supply.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2018-041921 filed on Mar. 8, 2018, the disclosure of which is incorporated herein in its entirety by reference.

### REFERENCE SIGNS LIST

101 Fan device
101x Operation device
106 Fan
111 Detection unit
116 FET
116x Adjustment unit
121 Capacitor
126 Processing unit
131 Recording unit
141 Communication unit
146 Detection unit
201 Power supply device
206 Current supply unit
211 Adjustment unit
216 Processing unit
226 Recording unit
221 Communication unit
301 Fan system

What is claimed is:

1. An operation device comprising:
an operation unit configured to operate by a supply current from a power supply; and
an adjustment unit configured to decrease, in a case where a current value of the supply current exceeds a threshold value, the value of the supply current.

2. The operation device according to claim 1, wherein
the adjustment unit performs the decrease by actuating a switch.

3. The operation device according to claim 2, further comprising
a processing unit configured to switch a voltage level in the case, wherein
the switch performs the actuation by the switching.

4. The operation device according to claim 3, wherein
the switch includes a semiconductor switch.

5. The operation device according to claim 4, wherein
the semiconductor switch is a field effect transistor, and
the voltage level is input to a gate of the field effect transistor.

6. The operation device according to claim 5, wherein,
when the current value falls below a threshold value after the case, the voltage level is returned to a level before the switching.

7. The operation device according to claim 2, wherein
the actuation is a change of a control signal that adjusts the supply current.

8. The operation device according to claim 7, wherein
the change is enabling and disabling.

9. The operation device according to claim 7, wherein
the control signal is a pulse width modulation control signal.

10. The operation device according to claim 7, wherein
the control signal performs the adjustment depending on an operation state of the operation unit.

11. The operation device according to claim 2, wherein
the actuation is supply and supply stop of the supply current being input to the the operation unit.

12. The operation device according to claim 1, wherein
an input unit of the supply current in the operation moans operation unit is grounded via a capacitor.

13. The operation device according to claim 1, wherein
the operation unit is a fan.

14. The operation device according to claim 1, further comprising
a detection unit configured to detect the current value.

15. The operation device according to claim 1, further comprising
a recording unit configured to hold the threshold value.

16. An operation system comprising:
the operation device according to claim 1; and
the power supply.
